(19) United States
(12) Patent Application Publication
(10) Pub. No.: US 2024/0392163 A1
(43) Pub. Date: Nov. 28, 2024

(54) ADDITIVE FOR CHEMICAL MECHANICAL POLISHING, METHOD FOR PRODUCING THE SAME, AND POLISHING LIQUID COMPOSITION

(71) Applicant: TOAGOSEI CO., LTD., Tokyo (JP)

(72) Inventors: Sachiko IMURA, Aichi (JP); Akitsugu SHIBATA, Aichi (JP); Akihiro GOTOU, Aichi (JP); Shinya KANBE, Aichi (JP)

(73) Assignee: TOAGOSEI CO., LTD., Tokyo (JP)

(21) Appl. No.: 18/693,607

(22) PCT Filed: Oct. 5, 2022
(86) PCT No.: PCT/JP2022/037217

§ 371 Date: Mar. 20, 2024

(30) Foreign Application Priority Data
Nov. 15, 2021 (JP) 2021-185491

(51) Int. Cl. C09G 1/02

(52) U.S. Cl. CPC C09G 1/02

(57) ABSTRACT

An additive is configured to be used for chemical mechanical polishing, and contains a polymer. The polymer contains a structural unit (A) derived from a vinyl monomer having a -(LO)n-R group, and a total content of the structural unit derived from a monomer containing one or more functional groups selected from the group consisting of a carboxylic acid group, a phosphoric acid group, a phosphonic acid group, a sulfuric acid group, a sulfonic acid group, and salts thereof is 0 to 0.6 mass % in polymer. The polymer has a dispersity represented by weight average molecular weight (Mw)/number average molecular weight (Mn) of 2.0 or less, wherein L represents an alkylene group having 4 or less carbon atoms, n represents an arbitrary integer of 3 to 150, and R represents a hydrogen atom or a monovalent hydrocarbon group having 1 to 4 carbon atoms.

### TECHNICAL FIELD

The present invention relates to an additive for chemical mechanical polishing (CMP), a method for producing the additive, and a polishing liquid composition, and more particularly, to an additive for chemical mechanical polishing, a method for producing the additive, and a polishing liquid composition, which are important in a manufacturing process of a semiconductor device or the like.

### BACKGROUND ART

Semiconductor devices are used for almost all electronic devices in daily life, such as information communication devices and home electric appliances, and are indispensable for modern life. In recent years, the role of semiconductor devices has further increased due to the spread of IoT, the utilization of cloud, and the like. Hitherto, high integration and large capacity of semiconductor chips have been achieved at a significant speed, but the demand for high performance has yet to be satisfied, and the importance of fine processing technology is increasing. In particular, a chemical mechanical polishing (CMP) technique is extremely important in realizing highly accurate multilayer wiring formation, and is frequently used in each stage of a semiconductor device manufacturing process such as planarization of an insulating film, metal plug formation, or embedded wiring formation.

In CMP, a polishing liquid is used for improving polishing speed and processing accuracy. The polishing liquid generally includes abrasive grains, a polishing accelerator, a water-soluble polymer, a surfactant, and the like. Among these, the water-soluble polymer, the surfactant, and the like are added to the polishing liquid for the purpose of improving the flatness of an object to be polished and reducing surface defects, and have an effect of protecting the surface by being adsorbed on the surface of a polished film, and also contributing to the reduction of an excessive polishing action. However, if the adsorption property to the polished film is too strong, there is a problem that a sufficient polishing speed cannot be obtained.

### PRIOR ART LITERATURE

### Patent Literature

Patent Literature 1: JP-A-2000-017195
Patent Literature 2: JP-A-2007-318072
Patent Literature 3: WO-A-2009/104334

### SUMMARY OF INVENTION

### Problems to be Solved by Invention

Patent Literature 1 discloses a polishing liquid composition containing a copolymer of an ammonium acrylate salt and methyl acrylate, and cerium oxide particles. The use of this polishing liquid composition is considered to more improve the flatness of the polished surface as compared with a case of using a polishing liquid containing no acrylic copolymer. However, the flatness is not sufficient. For example, when the above-described polishing liquid composition is used for polishing a polished film having an uneven surface, a concave portion is also polished at the same time in addition to a convex portion, thereby causing a portion particularly corresponding to the concave portion of the polished surface to bend like a dish shape. This phenomenon is called dishing, and there is a problem that this phenomenon is likely to occur when the ratio of the total area of the concave portion viewed in a plan view of the uneven surface is large.

In order to avoid dishing as described above and obtain a polished surface having high flatness, Patent Literature 2 proposes a polishing liquid composition containing ceria particles as abrasive grains, dihydroxyethyl glycine, and polyoxyalkylene alkylether as additives. Patent Literature 2 proposes that these two compounds are adsorbed to the abrasive grains and a polished film respectively, and a concave portion of the polished film is protected, thereby preventing excessive polishing and obtaining a flat surface, but since a surfactant has a small molecular weight, adsorption to the polished film is weak, and the protective effect is not sufficient.

Patent Literature 3 proposes a graft polymer containing an anionic functional group in a main polymer and polyalkylene glycol in a branch as a dishing reducer for copper. It is proposed that the anionic functional group of the main polymer is adsorbed to a copper surface and the polishing speed is adjusted, and as a result, a smooth surface is obtained, but there is a problem that productivity is reduced because the polishing speed is lowered.

The present invention has been made in view of the above circumstances, and an object of the present invention is to provide an additive for chemical mechanical polishing, a method for producing the additive, and a polishing liquid composition capable of sufficiently increasing the polishing speed of a convex portion (oxide film) and significantly reducing dishing on an uneven surface to be polished.

### Means for Solving Problem

As a result of intensive studies to solve the above problems, the present inventors have found that the above problems can be solved by using an additive containing a polymer that has a narrow molecular weight distribution and a specific structural unit. The present invention has been completed based on this finding. According to the present specification, the following means are provided.

[1] An additive for chemical mechanical polishing containing a polymer (P),
wherein the polymer (P) contains a structural unit (A) derived from a vinyl monomer having a -(LO)n-R group,
a total content of a structural unit derived from a monomer(s) containing one or more functional groups selected from the group consisting of a carboxylic acid group, a phosphoric acid group, a phosphonic acid group, a sulfuric acid group, a sulfonic acid group, and salts thereof is 0 to 0.6 mass % in the polymer (P), and
a dispersity (PDI) of the polymer (P), which is represented by weight average molecular weight (Mw)/number average molecular weight (Mn), is 2.0 or less,
wherein L represents an alkylene group having 4 or less carbon atoms, n represents an arbitrary integer of 3 to 150, and R represents a hydrogen atom or a monovalent hydrocarbon group having 1 to 4 carbon atoms.

[2] The additive according to [1], wherein a number average molecular weight (Mn) of the polymer (P) is 1,000 to 100,000.

[3] The additive according to [1] or [2], wherein the polymer (P) further contains a structural unit (B) derived from at least one monomer except for the vinyl monomer having the -(LO)n-R group, the monomer being selected from the group consisting of an amide group-containing vinyl monomer and an ester group-containing vinyl monomer.

[4] The additive according to [3], wherein the structural unit (B) is derived from a (meth)acrylic acid ester and/or a (meth)acrylic acid amide type monomer.

[5] The additive according to [3] or [4], wherein the structural unit (B) is derived from a monomer having an SP value of 17 to 25 (J/cm³)^{0.5} as calculated by a Fedors' estimation method.

[6] The additive according to any one of [1] to [5], wherein the polymer (P) is a block polymer.

[7] The additive according to any one of [1] to [6], wherein the polymer (P) contains a polymer block A and a polymer block B,
the polymer block A has the structural unit (A), and
the polymer block B has the structural unit (B).

[8] The additive according to [7], wherein a ratio (A/B) of the polymer block A to the polymer block B of the polymer (P) is 50/50 to 99.9/0.1 in mass ratio.

[9] A polishing liquid composition for chemical mechanical polishing used for surface planarization of at least one of an insulating layer and a wiring layer, the polishing liquid composition containing the additive according to any one of [1] to [8] and cerium oxide and/or silica.

[10] A method for producing an additive for a chemical mechanical polishing liquid containing a polymer, comprising;
producing the polymer by a living radical polymerization method,
wherein the polymer contains a structural unit derived from a vinyl monomer having a -(LO)n-R group,
a total content of a structural unit derived from a monomer containing one or more functional groups selected from the group consisting of a carboxylic acid group, a phosphoric acid group, a phosphonic acid group, a sulfuric acid group, a sulfonic acid group, and salts thereof is 0 to 0.6 mass % in the polymer, and
a dispersity (PDI) of the polymer, which is represented by weight average molecular weight (Mw)/number average molecular weight (Mn), is 2.0 or less,
wherein L represents an alkylene group having 4 or less carbon atoms, n represents an arbitrary integer of 3 to 150, and R represents a hydrogen atom or a monovalent hydrocarbon group having 1 to 4 carbon atoms.

### Effects of Invention

According to the present invention, it is possible to provide an additive for chemical mechanical polishing capable of sufficiently increasing the polishing speed of a convex portion (oxide film) and significantly reducing dishing on an uneven surface to be polished. In addition, it is possible to provide a polishing liquid composition containing the additive and cerium oxide and/or silica. Furthermore, a method for producing the additive for a chemical mechanical polishing liquid containing a polymer can be provided.

### MODE FOR CARRYING OUT INVENTION

Hereinafter, the present invention will be described in detail. In the present specification, “(meth)acryl” means acryl and/or methacryl, and “(meth)acrylate” means acrylate and/or methacrylate. The “(meth)acryloyl group” means an acryloyl group and/or a methacryloyl group.

According to the present invention, an additive for chemical mechanical polishing capable of sufficiently increasing the polishing speed of a convex portion (oxide film) on an uneven surface to be polished and significantly reducing dishing, and a polishing liquid composition containing the additive and cerium oxide and/or silica are provided. Furthermore, a method for producing the additive for a chemical mechanical polishing liquid containing a polymer is provided.

Hereinafter, the additive for chemical mechanical polishing, the polishing liquid composition, and the method for producing the additive for a chemical mechanical polishing liquid containing a polymer, which are provided in the present invention, will be described in detail.

### <<Additive for Chemical Mechanical Polishing>>

The additive for chemical mechanical polishing provided in the present invention contains a polymer (P), wherein the polymer (P) contains a structural unit (A) derived from a vinyl monomer having a -(LO)n-R group, and the total content of a structural unit derived from a monomer containing one or more functional groups selected from the group consisting of a carboxylic acid group, a phosphoric acid group, a phosphonic acid group, a sulfuric acid group, a sulfonic acid group, and salts thereof is 0 to 0.6 mass % in the polymer (P), and the polymer (P) has a dispersity (PDI) represented by weight average molecular weight (Mw)/number average molecular weight (Mn) of 2.0 or less.

### <Polymer (P)>

The polymer (P) used in the present invention contains the structural unit derived from the vinyl monomer having the -(LO)n-R group. Examples of L in the polymer (P) include a methylene group, an ethylene group, a -CHMe- group, a n-propylene group, a -CHEt- group, a -CHMeCH2- group, a -CH2CHMe- group, a n-butylene group, a -CH(n-Pr)- group, a -CH (i-Pr)- group, a -CHEtCH2- group, a -CH2CHEt- group, a -CHMeCH2CH2- group, a -CH2CHMeCH2- group, and a -CH2CH2CHMe- group. All L in the polymer (P) may be the same group. In addition, L in the polymer (P) may contain two or more kinds of groups different from each other. In consideration of the industrial availability of raw materials and solubility of the polymer (P) in water, L in the polymer (P) is preferably any of the ethylene group, the -CHMeCH2- group, or the -CH2CHMe- group, and more preferably the ethylene group.

n in the polymer (P) is an arbitrary integer of 3 to 150. Considering that the -(LO)n-R group contained in the polymer (P) is involved in the reduction of dishing due to adsorption to an oxide film, protection of the oxide film, and high responsiveness to a change in polishing pressure, the upper limit of n is preferably 100 or less, more preferably 50 or less, still more preferably 30 or less, and still even more preferably 15 or less. The lower limit of n is preferably 4 or more, more preferably 5 or more, still more preferably 6 or more, and still even more preferably 7 or more. The preferable range of n can be represented by any combination of the numerical values exemplified in the above upper limit and lower limit. For example, the preferable range of n may be 4 or more and 100 or less, 5 or more and 50 or less, 6 or more and 30 or less, or 7 or more and 15 or less.

It is noted that in the case where L is composed of only one type of group, n is an arbitrary integer included in the above range. On the other hand, in the case where the L is composed of two groups, the -(LO)n-R group can be represented as a -(L¹O)n¹-(L²O)n²-R group. In this case, the total value of n¹ and n² is an arbitrary integer included in the above range. The same applies to a case where the L is composed of three or more kinds of groups.

R in the polymer (P) is a hydrogen atom or a monovalent hydrocarbon group having 1 to 4 carbon atoms. Examples of the monovalent hydrocarbon group having 1 to 4 carbon atoms include a methyl group, an ethyl group, a n-propyl group, an i-propyl group, a n-butyl group, an i-butyl group, a sec-butyl group, and a tert-butyl group. Considering the availability of industrial raw materials and the solubility of the polymer (P) in water, R in the polymer (P) is preferably the hydrogen atom or the methyl group, and more preferably the methyl group.

An anionic (co) polymer is usually adsorbed on a surface of a positively charged nitride film. As a result, the polishing selectivity with respect to the oxide film on the convex portion is enhanced, and a flat surface is obtained. However, when the nitride film is exposed and polishing is about to be completed, the polishing speed of the oxide film increases, which may cause dishing. In addition, in the case of the anionic additive, the stability of the polishing liquid composition changes due to a pH change, and this may cause polishing scratches due to coarsening of the abrasive grains. In consideration of these points, the content of the structural unit derived from the monomer containing one or more functional groups selected from the group consisting of the carboxylic acid group, the phosphoric acid group, the phosphonic acid group, the sulfuric acid group, the sulfonic acid group, and salts thereof with respect to the whole polymer (P) is preferably 0 to 0.6 mass % in total. The content of the structural unit derived from a monomer containing one or more functional groups selected from the group consisting of the carboxylic acid group, the phosphoric acid group, the phosphonic acid group, the sulfuric acid group, the sulfonic acid group, and salts thereof with respect to the whole polymer (P) is more preferably 0 to 0.5 mass %, still more preferably 0 to 0.4 mass %, even more preferably 0 to 0.3 mass %, and still even more preferably 0 to 0.2 mass %.

The polymer (P) has a dispersity (PDI) represented by weight average molecular weight (Mw)/number average molecular weight (Mn) of 2.0 or less. In a polymer having a function of dispersing abrasive grains, it is considered that the magnitude of the molecular weight affects its adsorption-desorption rate to the object to be polished, and it is generally considered that the smaller the molecular weight of the polymer, the higher the adsorption-desorption rate to the object to be polished. In addition, it is considered that a polymer having a large molecular weight is likely to form an aggregate structure of abrasive grains caused by a shear force. Therefore, in the polymer having a function of dispersing abrasive grains, a narrow molecular weight distribution is preferred. From such a viewpoint, the PDI of the polymer (P) is preferably 1.8 or less, more preferably 1.5 or less, still more preferably 1.3 or less, and still even more preferably 1.2 or less. The lower limit value of the PDI is usually 1.0. It is noted that, in the present specification, the number average molecular weight (Mn) and the weight average molecular weight (Mw) of the polymer are values in terms of polystyrene measured by gel permeation chromatography (GPC). Details of the molecular weight measurement will be described in the section of Examples.

The number average molecular weight (Mn) of the polymer (P) is preferably 1,000 to 100,000. When Mn is 1,000 or more, a decrease in the polishing speed can be curtailed while sufficiently securing the wettability of the surface of the object to be polished When Mn is 100,000 or less, aggregation of abrasive grains caused by a shearing force can be sufficiently reduced, and the generation of defects such as scratches during polishing can be sufficiently avoided. From such a viewpoint, Mn of the polymer (P) is more preferably 1,500 or more, still more preferably 2,000 or more, and still even more preferably 2,500 or more. The upper limit of Mn of the polymer (P) is more preferably 60,000, still more preferably 30,000, even more preferably 10,000, and still even more preferably 6,000. The preferred range of the number average molecular weight can be represented by any combination of the numerical values exemplified in the above upper limit and lower limit. For example, the preferred range of the polymer (P) may be 1,500 or more and 60,000 or less, 2,000 or more and 30,000 or less, or 2,500 or more and 10,000 or less.

Although the details of the method for producing the polymer (P) will be described later, for example, the polymer (P) can be produced by polymerizing monomer components containing the vinyl monomer that has the -(LO)n-R group. The vinyl monomer having the -(LO)n-R group is not particularly limited as long as it is a compound having both a polymerizable vinyl group and the -(LO)n-R group.

Examples of the compound having the polymerizable vinyl group include ester compounds or amide-type compounds of unsaturated acids such as (meth)acrylic acid, crotonic acid, maleic acid, and itaconic acid, aromatic vinyl compounds, and vinyl ether compounds.

Specific examples of the vinyl monomer having the -(LO)n-R group that can be used in the present invention include N-[2-[2-(2-methoxyethoxy)ethoxy]ethyl](meth)acrylamide, 1-[(meth)acryloylamino]-3,6,9,12,15,18,21-heptaoxadocosane, polyethylene glycol mono(meth)acrylate, polypropylene glycol mono(meth)acrylate, polytetramethylene glycol mono(meth)acrylate, poly(ethylene glycol-propylene glycol) mono(meth)acrylate, poly(ethylene glycol-tetramethylene glycol) mono(meth)acrylate, poly(ethylene glycol-propylene glycol-tetramethylene glycol) mono(meth)acrylate, monomethoxy polyethylene glycol mono(meth)acrylate, monomethoxy polypropylene glycol mono(meth)acrylate, monomethoxy polytetramethylene glycol mono(meth)acrylate, monomethoxy poly(ethylene glycol-propylene glycol) mono(meth)acrylate, monomethoxy poly(ethylene glycol-tetramethylene glycol) mono(meth)acrylate, monomethoxy poly(ethylene glycol-propylene glycol-tetramethylene glycol) mono(meth)acrylate, monoethoxy polyethylene glycol mono(meth)acrylate, mono-n-propoxy polyethylene glycol mono(meth)acrylate, mono-i-propoxy polyethylene glycol mono(meth)acrylate, mono-n-butoxy polyethylene glycol mono(meth)acrylate, and mono-t-butoxy polyethylene glycol mono(meth)acrylate. Among them, polyethylene glycol mono(meth)acrylate and monomethoxy polyethylene glycol mono(meth)acrylate are preferable, polyethylene glycol monoacrylate and monomethoxy polyethylene glycol monoacrylate are more preferable, and monomethoxy polyethylene glycol monoacrylate is still more preferable.

Examples of commercially available products include BLEMMER AE series, AME series, AP series, PE series, PME series, PP series, and 50PEP series manufactured by NOF Corporation, AM series manufactured by SHIN-NAKAMURA CHEMICAL Co., Ltd., and LIGHT ACRYLATE MTG-A and LIGHT ACRYLATE 130A manufactured by KYOEISHA CHEMICAL Co., Ltd. It is noted that “BLEMMER” is a registered trademark of NOF Corporation, and “LIGHT ACRYLATE” is a registered trademark of KYOEISHA CHEMICAL Co., Ltd.

The content of the structural unit (A) derived from the vinyl monomer having the -(LO)n-R group with respect to the entire polymer (P) is preferably 50 mass % or more. The content of the structural unit (A) is more preferably 80 mass % or more, still more preferably 85 mass % or more, even more preferably 90 mass % or more, and still even more preferably 93 mass % or more. The upper limit of the content of the structural unit (A) is 100 mass %, preferably 99 mass %, more preferably 98 mass %, still more preferably 97 mass %, and still even more preferably 96 mass %. The preferred range of the content of the structural unit (A) described above can be represented by any combination of the numerical values exemplified in the above upper limit and lower limit. For example, a preferable range of the content of the structural unit (A) may be 50 mass % or more and 100 mass % or less, 80 mass % or more and 99 mass % or less, 85 mass % or more and 98 mass % or less, 90 mass % or more and 97 mass % or less, or 93 mass % or more and 96 mass % or less.

When the content of the structural unit derived from the vinyl monomer having the -(LO)n-R group is within the above range, the polymer (P) has high responsiveness to a change in polishing pressure. That is, when the oxide film is on a convex portion (when the polishing pressure is high), there is a tendency that the polymer (P) is not adsorbed and the polishing speed is not decreased. On the other hand, when polishing progresses, the nitride film is exposed, and the object to be polished becomes a concave portion (when the polishing pressure is low), there is a tendency that the polymer (P) is adsorbed to the interface of oxide film and excessive polishing is avoided.

These effects make it easy to obtain a good polished surface with reduced dishing without lowering the polishing speed.

The polymer (P) may be a homopolymer of the vinyl monomer having the -(LO)n-R group, or may be a polymer using a plurality of types of vinyl monomers having the -(LO)n-R group. The polymer (P) is preferably a copolymer of the vinyl monomer having a -(LO)n-R group and at least one monomer selected from the group consisting of an amide group-containing vinyl monomer and an ester group-containing vinyl monomer (however, excluding the vinyl monomer having a -(LO)n-R group). By using at least one monomer selected from the group consisting of the amide group-containing vinyl monomer and the ester group-containing vinyl monomer, the balance of hydrophilicity/hydrophobicity of the polymer (P) can be adjusted as desired, and the polymer (P) can be appropriately adsorbed to the interface of the oxide film to avoid excessive polishing.

Examples of the amide group-containing vinyl monomer include (meth)acrylamide derivatives such as (meth)acrylamide, tert-butyl(meth)acrylamide, N,N-dimethyl (meth)acrylamide, N,N-diethyl(meth)acrylamide, N-isopropyl(meth)acrylamide, N,N-dimethylaminopropyl(meth)acrylamide, and (meth)acryloylmorpholine; and N-vinylamide-based monomers such as N-vinylacetamide, N-vinylformamide, and N-vinylisobutyramide, and one or more of these can be used. Among them, (meth)acrylamide derivatives such as (meth)acrylamide, tert-butyl(meth)acrylamide, N,N-dimethyl(meth)acrylamide, N,N-diethyl(meth)acrylamide, N-isopropyl(meth)acrylamide, N,N-dimethylaminopropyl(meth)acrylamide, and (meth)acryloylmorpholine are preferable. Furthermore, a monomer having an SP value of 17 to 25 (J/cm³)^{0.5} calculated by the Fedors' estimation method (see Polymer Engineering & Science, Vol. 14, No. 2, pp. 147-154, etc. published in 1974) is more preferable, and a monomer having an SP value of 18 to 21.8 (J/cm³)^{0.5} is still more preferable. Specifically, tert-butylacrylamide and N-isopropylacrylamide are particularly suitable.

Examples of the ester group-containing vinyl monomer include: vinyl esters such as vinyl acetate and vinyl propionate; (meth)acrylic acid alkyl esters such as methyl (meth)acrylate, ethyl (meth)acrylate, n-propyl (meth)acrylate, isopropyl (meth)acrylate, n-butyl (meth)acrylate, isobutyl (meth)acrylate, tert-butyl (meth)acrylate, n-pentyl (meth)acrylate, amyl (meth)acrylate, n-hexyl (meth)acrylate, n-octyl (meth)acrylate, ethylhexyl (meth)acrylate, and n-decyl (meth)acrylate; aliphatic cyclic esters of (meth)acrylic acids such as cyclohexyl (meth)acrylate, methylcyclohexyl (meth)acrylate, tert-butylcyclohexyl (meth)acrylate, cyclododecyl (meth)acrylate, isobornyl (meth)acrylate, adamantyl (meth)acrylate, dicyclopentenyl (meth)acrylate, and dicyclopentanyl (meth)acrylate; aromatic esters of (meth)acrylic acid such as phenyl methacrylate, benzyl (meth)acrylate, phenoxymethyl (meth)acrylate, 2-phenoxyethyl (meth)acrylate, and 3-phenoxypropyl (meth)acrylate; hydroxyalkyl (meth)acrylates such as 2-hydroxyethyl (meth)acrylate, 3-hydroxypropyl (meth)acrylate, and 4-hydroxybutyl (meth)acrylate; (di) alkylaminoalkyl (meth)acrylates such as N-[2-(methylamino)ethyl](meth)acrylate, N-[2-(dimethylamino)ethyl](meth)acrylate, N-[2-(ethylamino)ethyl](meth)acrylate, and N-[2-(diethylamino)ethyl](meth)acrylate; epoxy group-containing (meth)acrylic acid esters such as glycidyl (meth)acrylate, 4-hydroxybutyl (meth)acrylate glycidyl ether, and 3,4-epoxycyclohexylmethyl (meth)acrylate; alkoxyalkyl (meth)acrylates such as 2-methoxyethyl (meth)acrylate, 2-(2-methoxyethoxy)ethyl (meth)acrylate, and methoxydipropylene glycol (meth)acrylate.

Among them, a monomer having an SP value of 17 to 25 (J/cm³)^{0.5} calculated by the Fedors' estimation method is more preferable, and a monomer having an SP value of 18 to 21.8 (J/cm³)^{0.5} is still more preferable. Specifically, methyl acrylate, ethyl acrylate, n-propyl acrylate, and n-butyl acrylate are particularly suitable.

The polymer (P) may further have a structural unit (B) derived from at least one monomer selected from the group consisting of an amide group-containing vinyl monomer and an ester group-containing vinyl monomer (however, excluding the vinyl monomer having the -(LO)n-R group). The content of the structural unit (B), that is, the total of the content of the structural unit derived from the amide group-containing vinyl monomer (however, excluding the vinyl monomer having the -(LO)n-R group) and the content of the structural unit derived from the ester group-containing vinyl monomer (however, excluding the vinyl monomer having the -(LO)n-R group) with respect to the entire polymer (P) is 0 mass % or more. The content of the structural unit (B) is preferably 1 mass % or more, more preferably 2 mass % or more, still more preferably 3 mass % or more, and still even more preferably 4 mass % or more The upper limit of the content of the structural unit (B) is preferably 50 mass %, more preferably 20 mass %, still more preferably 15 mass %, and still even more preferably 10 mass %. The preferred range of the content of the structural unit (B) can be represented by any combination of the above lower limit and upper limit For example, a preferable range of the content of the structural unit (B) may be 1 mass % or more and 50 mass % or less, 2 mass % or more and 20 mass % or less, 3 mass % or more and 15 mass % or less, or 4 mass % or more and 10 mass % or less.

When the total content of the structural unit derived from the amide group-containing vinyl monomer and the structural unit derived from the ester group-containing vinyl monomer with respect to the entire polymer (P) is within the above range, a good polished surface with reduced dishing is easily obtained.

The polymer (P) may contain another copolymerizable monomer as a structural unit in addition to the vinyl monomer having the -(LO)n-R group and at least one monomer selected from the group consisting of the amide group-containing vinyl monomer and the ester group-containing vinyl monomer.

Specific examples of other copolymerizable monomers include: alkyl vinyl ethers such as methyl vinyl ether, ethyl vinyl ether, n-propyl vinyl ether, isopropyl vinyl ether, n-butyl vinyl ether, isobutyl vinyl ether, t-butyl vinyl ether, n-hexyl vinyl ether, 2-ethylhexyl vinyl ether, n-octyl vinyl ether, n-nonyl vinyl ether, and n-decyl vinyl ether; vinyl alcohols such as vinyl alcohol, 2-hydroxyethyl vinyl ether, diethylene glycol monovinyl ether, and 4-hydroxybutyl vinyl ether; aromatic vinyl compounds such as styrene, vinyltoluene, and vinylxylene; and α-olefins such as ethylene, propylene, and butylene. As other copolymerizable monomers, one kind or two or more kinds among them can be used in combination.

The content of the structural unit derived from the other copolymerizable monomer with respect to the entire polymer (P) is preferably 10 mass % or less. The content of the structural unit derived from the other monomer is more preferably 8 mass % or less, still more preferably 5 mass % or less, even more preferably 3 mass % or less, and still even more preferably 1 mass % or less.

In the case where the polymer (P) is a copolymer containing the vinyl monomer having the -(LO)n-R group, the molecular structure thereof is preferably a block copolymer.

Among the block copolymers, the polymer (P) is preferably a block copolymer containing a polymer block A that has the structural unit (A) derived from the vinyl monomer having the -(LO)n-R group and a polymer block B that has the structural unit (B) derived from at least one monomer selected from the group consisting of the amide group-containing vinyl monomer and the ester group-containing vinyl monomer (however, excluding the vinyl monomer having the -(LO)n-R group).

Conventionally, as a water-soluble polymer used as an additive for chemical mechanical polishing (CMP), a homopolymer or a random type copolymer has been used. However, in a polymer having a structure in which functional groups to be adsorbed to a substrate surface are disposed on the entire polymer structure, protection of the surface of the object to be polished is weak, and excessive polishing may occur in a state where polishing pressure is high because adsorption sites are not disposed collectively. On the other hand, in the case of the block copolymer, it is conceivable that because the copolymer has a structure in which the functional groups to be adsorbed to the substrate surface are disposed collectively, it can exhibit sufficient adsorbability and can avoid excessive polishing of the object to be polished.

### <Block Copolymer>

The block copolymer that can be suitably used in the present invention contains the polymer block A and the polymer block B.

### Polymer Block A

The polymer block A has a structural unit (A) derived from the vinyl monomer having the -(LO)n-R group. The polymer block A may be the homopolymer of the vinyl monomer having the -(LO)n-R group, or may be the polymer using a plurality of types of vinyl monomers having the -(LO)n-R group. As long as the effect of the present invention is not impaired, the polymer block A may be a copolymer of the vinyl monomer having the -(LO)n-R group, and at least one monomer selected from the group consisting of the amide group-containing vinyl monomer and the ester group-containing vinyl monomer (however, excluding the vinyl monomer having the -(LO)n-R group) and/or the other copolymerizable monomer.

The content of the structural unit (A) derived from the vinyl monomer having the -(LO)n-R group with respect to the entire polymer block A is preferably 80 mass % or more, and more preferably 90 mass % or more. The content of the structural unit (A) may be 95 mass % or more, 97 mass % or more, or 99 mass % or more. The upper limit of the content of the structural unit (A) is 100 mass %.

When the content of the structural unit (A) derived from the vinyl monomer having the -(LO)n-R group is within the above range, the block copolymer has high responsiveness to a change in polishing pressure. That is, when the oxide film is on a convex portion (when the polishing pressure is high), there is a tendency that the block copolymer is not adsorbed and the polishing speed is not decreased. On the other hand, when polishing progresses, the nitride film is exposed, and the object to be polished becomes a concave portion (when the polishing pressure is low), there is a tendency that the block copolymer is adsorbed to the interface of oxide film, and excessive polishing is avoided.

These effects make it easy to obtain a good polished surface with reduced dishing without lowering the polishing speed.

The weight average molecular weight of the polymer block A is preferably 500 or more, more preferably 900 or more, still more preferably 1,500 or more, even more preferably 2,100 or more, and still even more preferably 2,700 or more. The upper limit of the weight average molecular weight of the polymer block A is preferably 100,000, more preferably 60,000, still more preferably 30,000, even more preferably 10,000, and still even more preferably 6,000. The preferred range of the weight average molecular weight of the polymer block A can be represented by any combination of the lower limit and the upper limit. For example, a preferable range of the weight average molecular weight of the polymer block A may be 500 or more and 100,000 or less, 900 or more and 60,000 or less, 1,500 or more and 30,000 or less, 2,100 or more and 10,000 or less, or 2,700 or more and 6,000 or less.

When the weight average molecular weight of the polymer block A is in the above range, it is preferable from the viewpoint that a decrease in the polishing speed can be curtailed while sufficiently securing the wettability of the surface of the object to be polished. In addition, it is preferable from the viewpoint that the aggregation of the abrasive grains caused by the shearing force can be sufficiently reduced and the generation of defects such as scratches during polishing can be sufficiently avoided.

### Polymer Block B

The polymer block B has the structural unit (B) derived from at least one monomer selected from the group consisting of the amide group-containing vinyl monomer and the ester group-containing vinyl monomer (however, excluding the vinyl monomer having the -(LO)n-R group). The polymer block B may be a homopolymer of any one monomer selected from the group consisting of the amide group-containing vinyl monomer and the ester group-containing vinyl monomer (however, excluding the vinyl monomer having the -(LO)n-R group), or may be a polymer using two or more monomers selected from the group consisting of the amide group-containing vinyl monomer and the ester group-containing vinyl monomer (however, excluding the vinyl monomer having the -(LO)n-R group). As long as the effect of the present invention is not impaired, the polymer block B may be a copolymer of at least one monomer selected from the group consisting of the amide group-containing vinyl monomer and the ester group-containing vinyl monomer (however, excluding the vinyl monomer having the -(LO)n-R group), and the vinyl monomer having the -(LO)n-R group and/or the other copolymerizable monomer.

The total of the content of the structural unit derived from the amide group-containing vinyl monomer (however, excluding the vinyl monomer having the -(LO)n-R group) and the content of the structural unit derived from the ester group-containing vinyl monomer (however, excluding the vinyl monomer having the -(LO)n-R group) with respect to the entire polymer block B, that is, the content of the structural unit (B) is preferably 80 mass % or more and more preferably 90 mass % or more. The total content of the structural unit (B) may be 95 mass % or more, 97 mass % or more, or 99 mass % or more.

The upper limit of the total content of the structural unit (B) is 100 mass %.

The weight average molecular weight of the polymer block B is preferably 100 or more, more preferably 120 or more, still more preferably 130 or more, even more preferably 140 or more, and still even more preferably 150 or more. The upper limit of the weight average molecular weight of the polymer block B is preferably 50,000, more preferably 10,000, still more preferably 5,000, even more preferably 1,000, and still even more preferably 500. The preferred range of the weight average molecular weight of the polymer block B can be expressed by arbitrarily combining the above lower limit and upper limit. For example, the preferable range of the weight average molecular weight of the polymer block B may be 100 or more and 50,000 or less, 120 or more and 10,000 or less, 130 or more and 5,000 or less, 140 or more and 1,000 or less, or 150 or more and 500 or less.

The block copolymer that can be suitably used in the present invention may have one or more polymer blocks A and one or more polymer blocks B, respectively. Examples of such a block copolymer include an AB diblock copolymer composed of the polymer block A and the polymer block B, an ABA triblock copolymer composed of the polymer block A/the polymer block B/the polymer block A and a BAB triblock copolymer. In addition, the block copolymer may be a multiblock copolymer having four or more polymer blocks, or may be a block copolymer containing a polymer block C other than the polymer block A and the polymer block B and having a structure such as ABC or ABCA. Among them, the block copolymer preferably has the AB structure from the viewpoint that the possibility of contamination with various impurities decreases because of fewer production steps than the ABC structure and the like, and a high-purity product can be produced.

The mass ratio (A/B) between the polymer block A and the polymer block B in the block copolymer is preferably 50/50 to 99.9/0.1, more preferably 80/20 to 99/1, and still more preferably 90/10 to 98/2. The mass ratio (A/B) between the polymer block A and the polymer block B in the block copolymer may be 93/7 to 97/3. When the mass ratio is within this range, the block copolymer tends to be adsorbed to the oxide film and to exhibit a protective effect. In addition, the block copolymer has high responsiveness to a change in polishing pressure. That is, when the oxide film is on a convex portion (when the polishing pressure is high), there is a tendency that the block copolymer is not adsorbed and the polishing speed is not decreased. On the other hand, when polishing progresses, the nitride film is exposed, and the object to be polished becomes a concave portion (when the polishing pressure is low), there is a tendency that the block copolymer is adsorbed to the interface of oxide film and excessive polishing is avoided. These effects are considered to make it easy to obtain a good polished surface with reduced dishing without lowering the polishing speed.

When the block copolymer contains a polymer block C other than the polymer block A and the polymer block B, the mass ratio of the sum of the polymer block A and the polymer block B to the whole block copolymer is preferably 90 mass % or more and more preferably 95 mass % or more. The mass ratio of the sum of the polymer block A and the polymer block B to the whole block copolymer may be 98 mass % or more or 99 mass % or more.

The additive for chemical mechanical polishing provided in the present invention is an additive for chemical mechanical polishing containing the polymer (P),
wherein the polymer (P) contains the structural unit (A) derived from the vinyl monomer having the -(LO)n-R group,
a total content of a structural unit derived from the monomer containing one or more functional groups selected from the group consisting of the carboxylic acid group, the phosphoric acid group, the phosphonic acid group, the sulfuric acid group, the sulfonic acid group, and salts thereof is 0 to 0.6 mass % in the polymer (P), and
the polymer (P) has a dispersity (PDI) represented by weight average molecular weight (Mw)/number average molecular weight (Mn) of 2.0 or less. Therefore, the additive for chemical mechanical polishing provided in the present invention may be in the form of a single component containing only the polymer (P), or may be in the form of containing a component different from the polymer (P) (hereinafter, also referred to as “other component”) together with the polymer (P).

The additive for chemical mechanical polishing provided in the present invention may contain a solvent as the other component. Examples of the solvents include water, an organic solvent, and a mixed solvent of water and an organic solvent. Among them, a solvent capable of dissolving the polymer (P) is preferable, water or a mixed solvent of water and an organic solvent capable of dissolving in water is more preferable, and water is particularly preferable. Examples of the organic solvent to be used together with water include alcohols such as methanol, ethanol, propanol, and butanol; ketones such as acetone and methyl ethyl ketone; alkylene glycols such as ethylene glycol and propylene glycol; ethers such as ethylene glycol monomethyl ether, propylene glycol monomethyl ether, ethylene glycol dimethyl ether, and tetrahydrofuran; esters such as ethylene glycol monomethyl ether acetate and ethyl acetate; amide-based solvents such as N,N-dimethylformamide and N,N-dimethylacetamide; and nitrile-based solvents such as acetonitrile. As the organic solvent, one kind can be used alone, or two or more kinds can be used in combination.

When the additive for chemical mechanical polishing provided in the present invention contains the polymer (P) and the solvent, the content of the polymer (P) is preferably 1 mass % or more, more preferably 5 mass % or more, and still more preferably 10 mass % or more, with respect to the total mass of the polymer (P) and the solvent, from the viewpoint of sufficiently bringing the surface of the object to be polished and the surface of the polishing pad into contact with the polymer (P). The upper limit of the content of the polymer (P) is preferably 70 mass %, more preferably 60 mass %, and still more preferably 50 mass % with respect to the total mass of the polymer (P) and the solvent from the viewpoint of avoiding deterioration in handleability due to an excessively high viscosity. The preferred range of the content of the polymer (P) can be represented by any combination of the lower limit and the upper limit. For example, a preferable range of the content of the polymer (P) may be 1 mass % or more and 70 mass % or less, 5 mass % or more and 60 mass % or less, or 10 mass % or more and 50 mass % or less, with respect to the total mass of the polymer (P) and the solvent.

### <<Method for Producing Polymer for Polishing Liquid Additive>>

The method for producing the polymer for polishing liquid additive, that is, the polymer (P) that can be suitably used in the present invention is not particularly limited as long as the effect of the present invention is not impaired. For example, the polymer (P) can be produced by polymerizing the monomer described above with a known radical polymerization method such as a solution polymerization method or bulk polymerization. In the case of the solution polymerization method, for example, a target polymer can be obtained by charging a solvent and a monomer into a reactor, adding a polymerization initiator, and performing thermal polymerization.

Alternatively, first, a vinyl-based polymer that contains a functional group having reactivity with an alcohol or an amino group, such as a carboxyl group, an acid anhydride group, or an epoxy group is produced by a known method. The vinyl-based polymer includes, for example, a poly(meth)acrylic acid or a polymer containing an acid anhydride structure or an epoxy group. Next, the obtained polymer and an alcohol having the -(LO)n-R group and/or an amine compound having the -(LO)n-R group may be subjected to an esterification reaction, an amidation reaction, an etherification reaction, or an amination reaction under known conditions in the presence of an acidic catalyst, a basic catalyst, a dehydration-condensation agent, or the like, thereby producing the polymer (P). In addition, in order to adjust the content of the acidic functional group, a known capping reaction such as a methyl esterification reaction may be performed.

The polymer (P) produced as described above may be subjected to a known polymer purification method such as a reprecipitation method or a method using a porous material to be purified so that the dispersity (PDI) represented by weight average molecular weight (Mw)/number average molecular weight (Mn) is 2.0 or less.

Examples of a suitable method for producing the polymer (P) include various controlled polymerization methods such as living radical polymerization and living anion polymerization. Among them, the living radical polymerization method is preferable from the view point that controllability of the dispersity (PDI) of molecular weight is high and a polymer with excellent dispersion stability of abrasive grains can be produced, and the view point that the operation is simple and applicable to a wide range of monomers. In the case of employing the living radical polymerization method, the polymerization mode is not particularly limited The polymerization can be performed by various modes such as bulk polymerization, solution polymerization, emulsion polymerization, mini-emulsion polymerization, and suspension polymerization.

For example, in the case of employing the living radical polymerization method to produce the polymer (P) by solution polymerization, the desired polymer (P) can be obtained by charging a solvent and a monomer into a reactor, adding a radical polymerization initiator, and performing polymerization preferably by heating. In the polymerization, any process such as a batch process, a semi-batch process, a dry continuous polymerization process, or a continuous stirring tank process (CSTR) may be adopted.

In the production of the polymer (P), as the living radical polymerization method, a polymerization method using a known polymerization mechanism can be adopted. Specific examples of the living radical polymerization method to be used include the living radical polymerization method by a chain exchange mechanism, the living radical polymerization method by a bond-dissociation mechanism, and the living radical polymerization method by an atom transfer mechanism. Specific examples thereof include, as living radical polymerization by the chain exchange mechanism, a reversible addition-fragmentation chain transfer polymerization method (RAFT method), an iodine transfer polymerization method, a polymerization method using an organic tellurium compound (TERP method), a polymerization method using an organic antimony compound (SBRP method), and a polymerization method using an organic bismuth compound (BIRP method); as living radical polymerization by the bond-dissociation mechanism, a nitroxy radical method (NMP method); and as living radical polymerization by the atom transfer mechanism, an atom transfer radical polymerization method (ATRP method). Among them, the living radical polymerization method by the chain exchange mechanism is preferable from the viewpoint of being applicable to the widest range of vinyl monomers and having excellent controllability of polymerization. In addition, the RAFT method or the NMP method is preferable in that pollution of the object to be polished due to contamination of the metal or the metalloid compound can be avoided In addition, the RAFT method is particularly preferable from the viewpoint of easy synthesis in an aqueous system that does not require a high temperature.

In the RAFT method, polymerization proceeds via a reversible chain transfer reaction in the presence of a polymerization control agent (RAFT agent) and a radical polymerization initiator. As the RAFT agent, various known RAFT agents such as a dithioester compound, a xanthate compound, a trithiocarbonate compound, and a dithiocarbamate compound can be used. Among them, the trithiocarbonate compound and the dithiocarbamate compound are preferable from the viewpoint that a polymer having a smaller molecular weight dispersity can be obtained. As the RAFT agent, a monofunctional compound having only one active point may be used, or a polyfunctional compound having two or more active points may be used. The usage of the RAFT agent is appropriately adjusted depending on the type of the monomer to be used, the RAFT agent, and the like.

As the radical polymerization initiator to be used in the polymerization by the RAFT method, known radical polymerization initiators such as an azo compound, an organic peroxide, and a persulfate can be used. Among these, the azo compound is preferable in that it is easy to handle in terms of safety, and a side reaction during radical polymerization is not likely to occur. Specific examples of the azo compound include 2,2′-azobis(isobutyronitrile), 2,2′-azobis(2,4-dimethylvaleronitrile), 4,4′-azobis(4-cyanovaleric acid), 2,2′-azobis(4-methoxy-2,4-dimethylvaleronitrile), dimethyl-2,2′-azobis(2-methylpropionate), 2,2′-azobis(2-methylbutyronitrile), 1,1′-azobis(cyclohexane-1-carbonitrile), 2,2′-azobis [N-(2-propenyl)-2-methylpropionamide], and 2,2′-azobis(N-butyl-2 methylpropionamide). Only one kind of these radical polymerization initiators may be used, or two or more kinds of radical polymerization initiators may be used in combination.

Although the usage of the radical polymerization initiator is not particularly limited, the usage is preferably 0.5 mol or less, and more preferably 0.2 mol or less, with respect to 1 mol of the RAFT agent, from the viewpoint of obtaining a polymer having a smaller molecular weight dispersity. From the viewpoint of stably performing the polymerization reaction, the lower limit of the usage of the radical polymerization initiator is preferably 0.01 mol, more preferably 0.05 mol, with respect to 1 mol of the RAFT agent. The usage of the radical polymerization initiator with respect to 1 mol of the RAFT agent is preferably 0.01 to 0.5 mol, and more preferably 0.05 to 0.2 mol.

In the case of using a solvent in living radical polymerization, examples of the polymerization solvent include aromatic compounds such as benzene, toluene, xylene, and anisole; ester compounds such as methyl acetate, ethyl acetate, propyl acetate, and butyl acetate; ketone compounds such as acetone and methyl ethyl ketone; dimethylformamide, acetonitrile, dimethylsulfoxide, alcohols, water, and the like. These polymerization solvents may be used alone, or two or more kinds of polymerization solvents may be used in combination.

In the polymerization reaction by the RAFT method, the reaction temperature is preferably 40° C. or higher and 100° C. or lower, more preferably 45° C. or higher and 90° C. or lower, and still more preferably 50° C. or higher and 80 or lower. The reaction temperature of 40° C. or higher is preferable in that the polymerization reaction can smoothly proceed, and the reaction temperature of 100° C. or lower is preferable in that side reactions can be curtailed and restrictions on usable initiators and solvents are relaxed. In addition, the reaction time can be appropriately set depending on the monomer to be used and the like, and is preferably 1 hour or longer and 48 hours or shorter, and more preferably 3 hours or longer and 24 hours or shorter. If necessary, the polymerization may be performed in the presence of a chain transfer agent (for example, an alkylthiol compound having 2 to 20 carbon atoms or the like). In the production process, particularly in a situation where a monomer having an acidic group is used, when there is a concern that metal may be mixed due to corrosion of the reactor or the like, it is preferable to perform production using equipment whose surface is coated with a fluorinated resin or the like. In this case, a container made of a resin having corrosion resistance or the like is preferably used as the storage container of the product or the like. In the case of using the resin container, the container is preferably made of a material in which metal mixing due to the dissolution of a filler or the like is reduced.

### <<Polishing Liquid Composition>>

The polishing liquid composition provided in the present invention contains at least the polymer (P) and abrasive grains. As the abrasive grains, at least one or more kinds of particles selected from the group consisting of known inorganic particles, organic particles, and organic-inorganic composite particles can be used.

Specific examples of the inorganic particles include cerium oxide (ceria), fumed silica, fumed alumina, fumed titania, and colloidal silica, and specific examples of the organic particles include (meth)acrylic copolymers such as polymethyl methacrylate, polystyrene and polystyrene copolymers, polyacetal, polyamide, polycarbonate, polyolefin and polyolefin-based copolymers, and phenoxy resin. The organic-inorganic composite particles may be those that are bonded or combined to an extent that they are not decomposed under the conditions used as the polishing liquid composition, such as those in which a functional group of an organic component and a functional group of an inorganic component are chemically bonded.

Among them, cerium oxide and/or silica is preferable because they have lower hardness than alumina and the like and have an advantage of being able to reduce the occurrence of defects on the polished surface. In particular, the cerium oxide is more suitable because the polished surface can be polished at a higher polishing speed as compared with silica, alumina, or the like.

The average particle size of the abrasive grains is not particularly limited, but is generally 1 nm to 500 nm. The average particle size of the abrasive grains is preferably 2 nm or more, and more preferably 3 nm or more from a viewpoint of securing a high polishing speed. The upper limit of the average particle size of the abrasive grains is preferably 300 nm and more preferably 100 nm from the viewpoint of reducing generation of scratches on the surface of the object to be polished. In the present specification, the average particle size of the abrasive grains is a primary particle size calculated using a specific surface area (m²/g) that is obtained by a BET (nitrogen adsorption) method.

The content of the abrasive grains in the polishing liquid composition is preferably 1 mass % or more, more preferably 10 mass % or more, and still more preferably 15 mass % or more from the viewpoint of realizing a high polishing speed. The upper limit of the content of the abrasive grains is preferably 50 mass %, more preferably 45 mass %, and still more preferably 40 mass % from the viewpoint of improving the smoothness of the object to be polished. The preferred range of the content of the abrasive grains can be represented by any combination of the lower limit and the upper limit. For example, a preferable range of the content of the abrasive grains may be 1 mass % or more and 50 mass %, 10 mass % or more and 45 mass % or less, or 15 mass % or more and 40 mass % or less.

The polishing liquid composition may contain a solvent. The solvent is preferably an aqueous solvent. Examples of the aqueous solvents include water and a mixed solvent of water and another solvent. As the other solvent, the solvent miscible with water is preferable, and examples thereof include alcohols such as ethanol. The polishing liquid composition may further contain a known additive such as a polishing accelerator, a pH adjusting agent, a surfactant, a chelating agent, or an anticorrosive as long as the effect of the present invention is not impaired.

The content of the polymer (P) is preferably an amount such that the solid content concentration of the polymer (P) is 0.001 mass % or more, and more preferably 1 mass % or more with respect to the total amount of the polishing liquid composition. The upper limit of the content of the polymer (P) is preferably set to an amount such that the solid content concentration of the polymer (P) is 10 mass %, and more preferably 5 mass % with respect to the total amount of the polishing liquid composition. The preferred range of the content of the polymer (P) can be represented by any combination of the lower limit and the upper limit. For example, the preferred range of the content of the polymer (P) may be an amount in which the solid content concentration of the polymer (P) is 0.001 mass % or more and 10 mass % or less, or 1 mass % or more and 5 mass % or less with respect to the total amount of the polishing liquid composition.

The polishing liquid composition is usually prepared as a slurry-like mixture by mixing the respective components by a known method. The viscosity of the polishing liquid composition at 25° C. can be appropriately selected according to an object to be polished, a shear rate at polishing, and the like, and is preferably in the range of 0.1 to 10 mPa·s, and more preferably in the range of 0.5 to 5 mPa·s.

Since the polishing liquid composition contains the polymer (P) as the additive, the polishing speed of a convex portion (oxide film) on an uneven surface to be polished is sufficiently high, and dishing can be significantly reduced.

Therefore, the polishing liquid composition provided in the present invention is suitable in that the occurrence of defects is reduced and an insulating film and a metal wiring having excellent surface smoothness can be obtained by using the polishing liquid for use in planarizing a surface of at least one of an insulating film and a metal wiring in a process of manufacturing a semiconductor element, specifically, for example, for planarizing an oxide film (silicon oxide film or the like) at the time of forming shallow trench isolation (STI), planarizing a surface of a metal wiring made of copper, a copper alloy, an aluminum alloy, or the like, planarizing a surface of an interlayer insulating film (oxide film), or the like.

### EXAMPLES

Hereinafter, the present invention will be specifically described based on Examples. It is noted that the present invention is not limited to these Examples. In the following description, “parts” and “%” mean parts by mass and % by mass, respectively, unless otherwise specified.

Methods for analyzing and producing the polymers used in Examples and Comparative Examples will be described below.

### <Measurement of Molecular Weight>

Using a gel permeation chromatograph apparatus (Model name: “HLC-8220”, manufactured by Tosoh Corporation), a number average molecular weight (Mn) and a weight average molecular weight (Mw) in terms of polystyrene were obtained under the following conditions. From the obtained value, the dispersity (PDI) of the molecular weight, that is, the ratio (Mw/Mn) of the weight molecular weight average amount (Mw) to the number average molecular weight (Mn) was calculated.

### •Measurement Conditions

Column: 4 columns of TSKgel SuperMultipore HxL-M manufactured by Tosoh Corporation
Column temperature: 40° C.
Eluent: tetrahydrofuran
Detector: RI
Flow rate: 0.6 mL/min

### <Mass Composition Ratio of Polymer>

The mass composition ratio of the polymer was calculated based on the reaction rate of monomers obtained by 1H-NMR measurement or gas chromatography (GC).

Measurement was performed at 25° C. using Ascend™ 400 nuclear magnetic resonance measurement apparatus manufactured by BRUKER as a 1H-NMR measuring apparatus with use of tetramethylsilane as a standard substance and deuterated chloroform as a solvent.

In addition, GC measurement was performed using Agilent 7820A (manufactured by Agilent Technologies) as an apparatus, VARIAN CP-SILSCB (30 m×0.32 mm, d.f.=3.0 μm) as a column, nitrogen as a carrier gas, and FID for detection.

### 1. Synthesis of Polymer

### Synthesis Example 1

A 1 L four-necked egg-plant shaped flask equipped with a stirrer, a thermometer, and a nitrogen inlet tube was charged with 150 g of pure water, 300 g of methoxypolyethylene glycol monoacrylate (manufactured by NOF Corporation, hereinafter, also referred to as “AME-400”), 0.48 g of 4,4′-azobis(4-cyanovaleric acid) (manufactured by FUJIFILM Wako Pure Chemical Corporation, hereinafter, also referred to as “V-501”), and 26.8 g of 3-((((1-carboxyethyl)thio)carbonothioyl)thio)propanoic acid (manufactured by BORON MOLECULAR, hereinafter, also referred to as “BM1429”) as a RAFT agent. The mixture was sufficiently degassed by nitrogen bubbling, and then the flask was heated in a thermostat at 70° C. to initiate polymerization. After 3 hours, the flask was cooled with water to stop the polymerization. The polymerization ratio of AME-400 at the time of stopping the polymerization was determined from 1H-NMR measurement and found to be 95%. Subsequently, 15.6 g of ethyl acrylate (hereinafter, also referred to as “EA”) was added to the flask, degassed sufficiently by nitrogen bubbling, and polymerization was initiated by heating the flask in a thermostat at 70° C. After 3 hours, the flask was cooled with water to stop the polymerization. The polymerization ratio of EA at the time of stopping the polymerization was determined from GC measurement and found to be 99%. The molecular weight of the water-soluble block copolymer (referred to as “polymer A”) thus obtained was determined by GPC measurement, and consequently, Mn was 3,030, Mw was 3,430, and PDI was 1.1.

### Synthesis Examples 2 to 22 and 26 to 35, Comparative Synthesis Examples 2 and 6

Water-soluble block copolymers (Polymers B to V, Z to i, m, q) were obtained in the same manner as in Synthesis Example 1 except that the charged raw materials were changed as shown in Tables 1 to 5. The results of determining the molecular weights of the polymers B to V, Z to i, m, and q by GPC measurement are shown in Tables 1 to 5.

### Synthesis Example 23

A 1 L four-necked egg-plant shaped flask equipped with a stirrer, a thermometer, and a nitrogen inlet tube was charged with 150 g of pure water, 300 g of AME-400, 0.48 g of V-501, and 25.4 g of BM1429, which were sufficiently degassed by nitrogen bubbling, and then the flask was heated in a thermostat at 70° C. to initiate polymerization. After 5 hours, the flask was cooled with water to stop the polymerization. The polymerization ratio of AME-400 at the time of stopping the polymerization was determined from 1H-NMR measurement and found to be 99%. The molecular weight of the resulting water-soluble polymer (referred to as “polymer W”) was determined by GPC measurement, and consequently, Mn was 3,000, Mw was 3,390, and PDI was 1.1.

### Synthesis Example 24 to 25

Water-soluble polymers (Polymer X, Y) were obtained in the same manner as in Synthesis Example 23 except that the charged raw materials were changed as shown in Table 3. The results of determining the molecular weights of the polymers X and Y by GPC measurement are shown in Table 3.

### Synthesis Example 36

A 1 L four-necked egg-plant shaped flask equipped with a stirrer, a thermometer, and a nitrogen inlet tube was charged with 150 g of pure water, 300 g of AME-400, 0.48 g of V-501, and 26.8 g of BM1429, which were sufficiently degassed by nitrogen bubbling, and then the flask was heated in a thermostat at 70° C. to initiate polymerization. After 3 hours, the flask was cooled with water to stop the polymerization. The polymerization ratio of AME-400 was determined from 1H-NMR measurement to be 95%. Subsequently, 7.8 g of EA was added to the flask and sufficiently degassed by nitrogen bubbling, and then the flask was heated in a thermostat at 70° C. to start polymerization. After 3 hours, the flask was cooled with water to stop the polymerization. The reaction rate of EA was 95% as determined from GC measurement. Subsequently, 7.8 g of t-butylacrylamide (hereinafter, also referred to as “TBAM”) was added to the flask, and after sufficient degassing by nitrogen bubbling, the flask was heated in a thermostat at 70° C. to initiate polymerization. After 3 hours, the flask was cooled with water to stop the polymerization. The polymerization ratio of TBAM was determined from GC measurement and found to be 90%. The molecular weight of the resulting water-soluble block copolymer (referred to as “polymer j”) was determined by GPC measurement, and consequently, Mn was 3,120, Mw was 3,490, and PDI was 1.1.

### Synthesis Example 37

Water-soluble polymer k was obtained in the same manner as in Synthesis Example 36 except that the charged raw materials were changed as shown in Table 4. The results of determining the molecular weight of the polymer k by GPC measurement are shown in Table 4.

### Comparative Synthesis Example 1

Water-soluble polymer I was obtained in the same manner as in Synthesis Example 23 except that the charged raw materials were changed as shown in Table 5. The results of determining the molecular weight of the polymer 1 by GPC measurement are shown in Table 5.

### Comparative Synthesis Example 3

100 g of acetonitrile was added to a 1 L four-necked egg-plant shaped flask equipped with a stirrer, a thermometer, and a nitrogen inlet tube, and the mixture was stirred while being maintained at 75° C. Next, an initiator solution obtained by dissolving 0.10 g of 2,2′-azobis(2,4-dimethylvaleronitrile) (manufactured by FUJIFILM Wako Pure Chemical Corporation, hereinafter, also referred to as “V-65”) in 7.2 g of acetonitrile was added to the flask. Thereafter, 432 g of AME-400 and a chain transfer agent solution obtained by dissolving 50 g of 3-methoxybutyl 3-mercaptopropionate (hereinafter, also referred to as “MPMB”) in 64 g of acetonitrile were each supplied to the flask over 3 hours. In addition, simultaneously with the chain transfer agent solution, an initiator solution obtained by dissolving 0.40 g of V-65 in 40 g of acetonitrile was supplied to the flask over 5 hours. After completion of the initiator solution feed, the contents of the flask were heated and stirred for a further 1.5 hours. Thereafter, the flask was cooled with water to stop the polymerization. Thereafter, the solvent was removed from the contents of the flask with an evaporator. The polymerization ratio of AME-400 at the time of stopping the polymerization was determined from 1H-NMR measurement and found to be 99%. When the molecular weight of the resulting water-soluble polymer (referred to as “polymer n”) was determined by GPC measurement, Mn was 2,600, Mw was 5,720, and PDI was 2.2.

### Comparative Synthesis Example 4 to 5

Water-soluble copolymers (polymers o to p) were obtained in the same manner as in Comparative Synthesis Example 3 except that the charged raw materials were changed as shown in Table 5. The results of determining the molecular weights of the polymers o to p by GPC measurement are shown in Table 5.

TABLE 1

| | | | Synthesis | Synthesis | Synthesis | Synthesis | Synthesis | Synthesis | Synthesis | Synthesis | Synthesis |
|---|---|---|---|---|---|---|---|---|---|---|---|
| | | | Example 1 | Example 2 | Example 3 | Example 4 | Example 5 | Example 6 | Example 7 | Example 8 | Example 9 |
| | | | Polymer | Polymer | Polymer | Polymer | Polymer | Polymer | Polymer | Polymer | Polymer |
| | | | A | B | C | D | E | F | G | H | I |
| Charge | 1st | AME-400 | 300 | 300 | 300 | 300 | 300 | 300 | 300 | 300 | 300 |
| (g) | monomer | | | | | | | | | | |
| | Initiator | V-501 | 0.48 | 0.48 | 0.47 | 0.44 | 0.23 | 0.48 | 0.48 | 0.46 | 0.23 |
| | Solvent | Pure water | 150 | 150 | 140 | 135 | 120 | 150 | 150 | 135 | 120 |
| | RAFT | BM1429 | 26.8 | 40.2 | 16.1 | 1.6 | 0.40 | 26.8 | 40.2 | 1.6 | 0.40 |
| | agent | | | | | | | | | | |
| | 2nd | EA | 15.6 | 15.6 | 15.6 | 15.6 | 15.6 | — | — | — | — |
| | monomer | NIPAM | — | — | — | — | — | 15.6 | 15.6 | 15.6 | 15.6 |

| | | | | | | | | | | |
|---|---|---|---|---|---|---|---|---|---|---|
| Analysis | 1st reaction rate (%) | 95 | 95 | 95 | 95 | 95 | 95 | 95 | 95 | 95 |
| | 2nd reaction rate (%) | 99 | 94 | 99 | 99 | 99 | 90 | 95 | 90 | 85 |
| | 1st block ratio (wt %) | 94.9 | 95.1 | 94.9 | 94.9 | 94.9 | 95.3 | 95.1 | 95.1 | 95.1 |
| | 2nd block ratio (wt %) | 5.1 | 4.9 | 5.1 | 5.1 | 5.1 | 4.7 | 4.9 | 4.9 | 4.9 |
| | Mn | 3,030 | 2,120 | 5,090 | 50,300 | 203,000 | 2,120 | 2,020 | 50,700 | 201,200 |
| | Mw | 3,430 | 2,370 | 5,600 | 56,800 | 229,000 | 3,430 | 2,300 | 57,800 | 225,000 |
| | Mw/Mn | 1.1 | 1.1 | 1.1 | 1.1 | 1.1 | 1.1 | 1.1 | 1.1 | 1.1 |

TABLE 2

| | | | Synthesis | Synthesis | Synthesis | Synthesis | Synthesis | Synthesis | Synthesis | Synthesis | Synthesis |
|---|---|---|---|---|---|---|---|---|---|---|---|
| | | | Example | Example | Example | Example | Example | Example | Example | Example | Example |
| | | | 10 | 11 | 12 | 13 | 14 | 15 | 16 | 17 | 18 |
| | | | Polymer | Polymer | Polymer | Polymer | Polymer | Polymer | Polymer | Polymer | Polymer |
| | | | J | K | L | M | N | O | P | Q | R |
| Charge | 1st | AME-400 | 300 | 300 | 300 | 300 | 300 | 300 | 300 | 300 | 300 |
| (g) | monomer | | | | | | | | | | |
| | Initiator | V-501 | 0.48 | 0.48 | 0.48 | 0.48 | 0.48 | 0.48 | 0.48 | 0.48 | 0.48 |
| | Solvent | Pure water | 150 | 150 | 150 | 150 | 150 | 150 | 150 | 150 | 150 |
| | RAFT | BM1429 | 26.8 | 26.8 | 26.8 | 26.8 | 26.8 | 26.8 | 26.8 | 26.8 | 26.8 |
| | agent | | | | | | | | | | |
| | 2nd | BA | 15.6 | — | — | — | — | — | — | — | — |
| | monomer | MA | — | 15.6 | — | — | — | — | — | — | — |
| | | HexA | — | — | 15.6 | — | — | — | — | — | — |
| | | TBAM | — | — | — | 15.6 | — | — | — | — | — |
| | | DMAA | — | — | — | — | 15.6 | — | — | — | — |
| | | DEAA | — | — | — | — | — | 15.6 | — | — | — |
| | | HEAA | — | — | — | — | — | — | 15.6 | — | — |
| | | DPM-A | — | — | — | — | — | — | — | 15.6 | — |
| | | HEA | — | — | — | — | — | — | — | — | 15.6 |

| | | | | | | | | | | |
|---|---|---|---|---|---|---|---|---|---|---|
| Analysis | 1st reaction rate (%) | 95 | 95 | 95 | 95 | 95 | 95 | 95 | 95 | 95 |
| | 2nd reaction rate (%) | 95 | 99 | 99 | 85 | 90 | 92 | 93 | 99 | 99 |
| | 1st block ratio | 94.9 | 95.0 | 95.1 | 95.6 | 95.3 | 95.2 | 95.2 | 95.1 | 94.9 |
| | (wt %) | | | | | | | | | |
| | 2nd block ratio | 5.1 | 5.0 | 4.9 | 4.4 | 4.7 | 4.8 | 4.8 | 4.9 | 5.1 |
| | (wt %) | | | | | | | | | |
| | Mn | 3,070 | 3,050 | 3,000 | 3,050 | 3,130 | 3,160 | 3,090 | 3,090 | 3,100 |
| | Mw | 3,500 | 3,500 | 3,360 | 3,420 | 3,380 | 3,570 | 3,380 | 3,400 | 3,510 |
| | Mw/Mn | 1.1 | 1.1 | 1.1 | 1.1 | 1.1 | 1.1 | 1.1 | 1.1 | 1.1 |

TABLE 3

| | | | Synthesis | Synthesis | Synthesis | Synthesis | Synthesis | Synthesis | Synthesis | Synthesis | Synthesis |
|---|---|---|---|---|---|---|---|---|---|---|---|
| | | | Example | Example | Example | Example | Example | Example | Example | Example | Example |
| | | | 19 | 20 | 21 | 22 | 23 | 24 | 25 | 26 | 27 |
| | | | Polymer | Polymer | Polymer | Polymer | Polymer | Polymer | Polymer | Polymer | Polymer |
| | | | S | T | U | V | W | X | Y | Z | a |
| Charge | 1st | AME-400 | 300 | 300 | 300 | 300 | 300 | 285 | 285 | 240 | 240 |
| (g) | monomer | PME-400 | — | — | — | — | — | — | — | 60 | 60 |
| | | EA | — | — | — | — | — | 15 | — | — | — |
| | | NIPAM | — | — | — | — | — | — | 15 | — | — |
| | Initiator | V-501 | 0.48 | 0.48 | 0.48 | 0.48 | 0.48 | 0.48 | 0.48 | 1.87 | 1.87 |
| | Solvent | Pure water | 150 | 150 | 150 | 150 | 150 | 150 | 150 | 150 | 150 |
| | RAFT | BM1429 | 28.3 | 29.8 | 28.3 | 29.8 | 25.4 | 25.4 | 25.4 | 26.8 | 26.8 |
| | agent | | | | | | | | | | |
| | 2nd | EA | 32 | 64 | — | — | — | — | — | 15.6 | — |
| | monomer | NIPAM | — | — | 32 | 64 | — | — | — | — | 15.6 |

| | | | | | | | | | | |
|---|---|---|---|---|---|---|---|---|---|---|
| Analysis | 1st reaction rate (%) | 95 | 95 | 95 | 95 | 99 | 99 | 99 | 95 | 95 |
| | 2nd reaction rate (%) | 99 | 97 | 90 | 90 | — | — | — | 99 | 90 |
| | 1st block ratio | 90.0 | 82.1 | 90.8 | 83.2 | 100 | 100 | 100 | 93.7 | 94.2 |
| | (wt %) | | | | | | | | | |
| | 2nd block ratio | 10.0 | 17.9 | 9.2 | 16.8 | — | — | — | 6.3 | 5.8 |
| | (wt %) | | | | | | | | | |
| | Mn | 3,060 | 3,080 | 3,120 | 3,050 | 3,000 | 3,050 | 3,090 | 3,100 | 3,090 |
| | Mw | 3,490 | 3,510 | 3,430 | 3,420 | 3,390 | 3,360 | 3,400 | 3,630 | 3,450 |
| | Mw/Mn | 1.1 | 1.1 | 1.1 | 1.1 | 1.1 | 1.1 | 1.1 | 1.2 | 1.1 |

TABLE 4

| | | | Syn- | Syn- | Syn- | Syn- | Syn- | Syn- | Syn- | Syn- | Syn- | Syn- |
|---|---|---|---|---|---|---|---|---|---|---|---|---|
| | | | thesis | thesis | thesis | thesis | thesis | thesis | thesis | thesis | thesis | thesis |
| | | | Ex- | Ex- | Ex- | Ex- | Ex- | Ex- | Ex- | Ex- | Ex- | Ex- |
| | | | ample | ample | ample | ample | ample | ample | ample | ample | ample | ample |
| | | | 28 | 29 | 30 | 31 | 32 | 33 | 34 | 35 | 36 | 37 |
| | | | Poly- | Poly- | Poly- | Poly- | Poly- | Poly- | Poly- | Poly- | Poly- | Poly- |
| | | | mer | mer | mer | mer | mer | mer | mer | mer | mer | mer |
| | | | b | c | d | e | f | g | h | i | j | k |
| Charge | 1st | AME-400 | — | — | — | — | — | — | 270 | 270 | 300 | 300 |
| (g) | monomer | MTG-A | 300 | 300 | — | — | — | — | — | — | — | — |
| | | AM-230G | — | — | 300 | 300 | — | — | — | — | — | — |
| | | AE-400 | — | — | — | — | 300 | 300 | — | — | — | — |
| | | ACMO | — | — | — | — | — | — | 30 | 30 | — | — |
| | Initiator | V-501 | 0.48 | 0.48 | 0.48 | 0.48 | 0.48 | 0.48 | 0.48 | 0.48 | 0.48 | 0.48 |
| | Solvent | Pure water | 150 | 150 | 150 | 150 | 150 | 150 | 150 | 150 | 150 | 150 |
| | RAFT | BM1429 | 26.8 | 26.8 | 26.8 | 26.8 | 26.8 | 26.8 | 26.8 | 26.8 | 26.8 | 26.8 |
| | agent | | | | | | | | | | | |
| | 2nd | EA | 15.6 | — | 15.6 | — | 15.6 | — | 15.6 | — | 7.8 | — |
| | monomer | NIPAM | — | — | 32 | 64 | — | — | — | — | 15.6 | — |
| | 3rd | TBAM | — | — | — | — | — | — | — | — | 7.8 | 7.8 |
| | monomer | | | | | | | | | | | |

| | | | | | | | | | | | |
|---|---|---|---|---|---|---|---|---|---|---|---|
| Analysis | 1st reaction rate (%) | 90 | 95 | 95 | 95 | 90 | 99 | 95 | 95 | 95 | 95 |
| | 2nd reaction rate (%) | 99 | 90 | 99 | 95 | 99 | 95 | 94 | 99 | 95 | 90 |
| | 3rd reaction rate | — | — | — | — | — | — | — | — | 90 | 90 |
| | 1st block ratio | 94.6 | 95.3 | 94.9 | 95.1 | 94.6 | 95.2 | 94.6 | 94.3 | 95.2 | 95.3 |
| | (wt %) | | | | | | | | | | |
| | 2nd block ratio | 5.4 | 4.7 | 5.1 | 4.9 | 5.4 | 4.8 | 5.4 | 5.7 | 2.5 | 2.3 |
| | (wt %) | | | | | | | | | | |
| | 3rd block ratio | — | — | — | — | — | — | — | — | 2.3 | 2.4 |
| | (wt %) | | | | | | | | | | |
| | Mn | 3,030 | 3,060 | 3,200 | 3,000 | 3,120 | 2,990 | 3,060 | 3,030 | 3,120 | 3,100 |
| | Mw | 3,400 | 3,490 | 3,620 | 3,420 | 3,490 | 3,380 | 3,490 | 3,330 | 3,490 | 3,410 |
| | Mw/Mn | 1.1 | 1.1 | 1.1 | 1.1 | 1.1 | 1.1 | 1.1 | 1.1 | 1.1 | 1.1 |

TABLE 5

| | | | Comparative | Comparative | Comparative | Comparative | Comparative | Comparative |
|---|---|---|---|---|---|---|---|---|
| | | | Synthesis | Synthesis | Synthesis | Synthesis | Synthesis | Synthesis |
| | | | Example 1 | Example 2 | Example 3 | Example 4 | Example 5 | Example 6 |
| | | | Polymer l | Polymer m | Polymer n | Polymer o | Polymer p | Polymer q |
| Charge | 1st | AME-400 | — | 300 | 432 | 410 | 410 | — |
| (g) | monomer | EA | — | — | — | 22 | — | — |
| | | NIPAM | — | — | — | — | 22 | — |
| | | AA | 150 | — | — | — | — | 150 |
| | Initiator | V-501 | 0.54 | 0.48 | — | — | — | 0.54 |
| | | V-65 | — | — | 0.50 | 0.50 | 0.50 | — |
| | Solvent | Pure water | 375 | 150 | — | — | — | 375 |
| | | Acetonitrile | — | — | 211 | 211 | 211 | — |
| | RAFT | BM1429 | 12.7 | 26.8 | — | — | — | 12.7 |
| | agent | | | | | | | |
| | Chain | MPMB | — | — | 50 | 50 | 50 | — |
| | transfer | | | | | | | |
| | agent | | | | | | | |
| | 2nd | NIPAM | — | — | — | — | — | 7.8 |
| | monomer | AA | — | 15.6 | — | — | — | — |

| | | | | | | | |
|---|---|---|---|---|---|---|---|
| Analysis | 1st reaction rate (%) | 98 | 95 | 99 | 99 | 99 | 98 |
| | 2nd reaction rate (%) | — | 99 | — | — | — | — |
| | 1st block ratio | 100 | 94.9 | 100 | 100 | 100 | 95.4 |
| | (wt %) | | | | | | |
| | 2nd block ratio | — | 5.1 | — | — | — | 4.6 |
| | (wt %) | | | | | | |
| | Mn | 3,050 | 3,020 | 2,600 | 2,700 | 2,670 | 3,100 |
| | Mw | 3,600 | 3,380 | 5,730 | 5,940 | 5,870 | 3,410 |
| | Mw/Mn | 1.1 | 1.1 | 2.2 | 2.2 | 2.2 | 1.1 |

The details of the compounds shown in Tables 1 to 11 are as follows.

AME-400: methoxypolyethylene glycol monoacrylate (n=9) (manufactured by NOF Corporation, trade name: BLEMMER AME-400)

PME-400: methoxypolyethylene glycol monomethacrylate (n=9) (manufactured by NOF Corporation, Trade name: BLEMMER PME-400)

MTG-A: methoxytriethylene glycol acrylate (manufactured by KYOEISHA CHEMICAL Co., Ltd., trade name: LIGHT ACRYLATE MTG-A)

AM-230G: methoxypolyethylene glycol acrylate (n=23) (manufactured by SHIN-NAKAMURA CHEMICAL Co., Ltd., trade name: NK ESTER AM-230G)

AE-400: polyalkylene glycol monoacrylate (n=10) (manufactured by NOF Corporation, trade name: BLEMMER AE-400)

EA: ethyl acrylate

NIPAM: N-isopropylacrylamide

ACMO: N-acryloylmorpholine

AA: acrylic acid

V-501: 4,4′-azobis(4-cyanovaleric acid) (manufactured by FUJIFILM Wako Pure Chemical Corporation)

V-65: 2,2′-azobis(2,4-dimethylvaleronitrile) (manufactured by FUJIFILM Wako Pure Chemical Corporation)

BM1429: 3-((((1-carboxyetbyl)thio)carbonothioyl)thio)propanoic acid (manufactured by BORON MOLECULAR)

MPMB: 3-methoxybutyl 3-mercaptopropionate

BA: n-butyl acrylate

MA: methyl acrylate

HexA: n-hexyl acrylate

TBAM: N-tert-butylacrylamide

DMAA: N,N-dimethylacrylamide

DEAA: N,N-diethylacrylamide

HEAA: N-(2-hydroxyethyl) acrylamide

DPM-A: methoxydipropylene glycol acrylate (manufactured by KYOEISHA CHEMICAL Co., Ltd., Trade name: Light Acrylate DPM-A)

HEA: 2-hydroxyethyl acrylate

XL-80: polyoxyalkylene branched decyl ether (surfactant manufactured by DKS Co. Ltd., trade name: NOIGEN (registered trademark) XL-80)

### 2. Measurement and Evaluation

### Example 1

500 parts of a polymer aqueous solution containing the polymer A at a solid content concentration of 0.5 mass % was prepared. Next, while stirring 500 parts of an aqueous dispersion of colloidal ceria (manufactured by NYACOL, trade name: NYACOL 80/10, particle concentration: 10%, average particle diameter: 80 nm), the polymer aqueous solution prepared above was added to obtain a polishing liquid composition.

### Example 2 to 37, Comparative Example 3 to 9

A polishing liquid composition was obtained in the same manner as in Example 1 except that the polymer A was changed to a polymer or a surfactant shown in Tables 6 to 11.

### Example 38

500 parts of a polymer aqueous solution containing the polymer A at a solid content concentration of 0.5 mass % was prepared. Next, while stirring 500 parts of an aqueous dispersion of colloidal silica (manufactured by FUSO CHEMICAL CO., LTD., trade name: Quartron PL-7, particle concentration: 23%, average particle diameter: 75 nm), the previously prepared polymer aqueous solution was added, and then the pH was adjusted to 9 with 28% aqueous ammonia to obtain a polishing liquid composition. “Quartron” is a registered trademark of FUSO CHEMICAL CO., LTD.

### Example 39

A polishing liquid composition was obtained in the same manner as in Example 38 except that the polymer A was changed to a polymer shown in Table 10.

### Comparative Example 1

While stirring 500 parts of an aqueous dispersion of colloidal ceria (manufactured by NYACOL, trade name: NYACOL 80/10, particle concentration: 10%, average particle diameter: 80 nm), 500 parts of pure water was added to obtain a polishing liquid composition.

### Comparative Example 2

While stirring 500 parts of an aqueous dispersion of colloidal silica (manufactured by FUSO CHEMICAL CO., LTD., trade name: Quartron PL-7, particle concentration: 23%, average particle diameter: 75 nm), 500 parts of pure water was added, and then the pH was adjusted to 9 with 28% aqueous ammonia to obtain a polishing liquid composition.

Using each polishing liquid composition prepared by the above methods, a polishing test was performed under the following conditions.

### <Polishing Conditions>

Polishing tester: manufactured by KEMET JAPAN, trade name: MAT-ARW-CMS

Polishing pad: manufactured by Rodel Nitta, trade name: IC-1000/Sub400

Platen rotation speed: 60 rpm

Carrier rotation speed: 61 rpm

Polishing liquid supply amount: 150 g/min

Polishing pressure: 1 psi, 3 psi, or 5 psi

### <RR Measurement/Evaluation Method>

A blanket wafer with a silicon oxide film of 1.4 μm formed on a 4 inch silicon substrate by CVD was used as a material to be polished, and polished for 1 minute under the above polishing conditions, and a polishing speed (RR) (unit: nm/min) was determined from a difference in residual film thickness before and after polishing. The residual film thickness was measured using an interference thickness meter.

Regarding the RR of each polishing liquid composition, the RR of each of the polishing liquid compositions of Examples 1 to 37 and Comparative Examples 3 to 9 was evaluated by the ratio to the RR of the polishing liquid composition of Comparative Example 1, and the RR of each of the polishing liquid compositions of Examples 38 to 39 was evaluated by the ratio to the RR of the polishing liquid composition of Comparative Example 2 (at 3 psi each). The evaluation criteria of RR were as follows. (The RR of each of Comparative Examples 1 to 2 was RRa, the RR of each of the polishing liquid compositions of Examples 1 to 37 and Comparative Examples 3 to 9 was RRb, and the calculated values of RRb/RRa are shown in Tables 6 to 11.) The polishing liquid composition of each of Comparative Examples 1 to 2 had RRb/RRa=1.00. Then, the dishing reduction performance was evaluated according to the following criteria based on the ratio (RR3/RR1) of RR (RR3) at 3 psi to RR (RR1) at 1 psi and the ratio (RR5/RR1) of RR (RR5) at 5 psi to RR1. When both criteria C or higher of RR and dishing reduction performance were satisfied, it was determined as pass.

### <Evaluation Criteria of RR>

A: RRb/RRa≥0.85

B: 0.85>RRb/RRa≥0.70

C: 0.70>RRb/RRa≥0.50

D: RRb/RRa<0.50

### <Evaluation Criteria of Dishing Reduction Performance>

A: RR3/RR1>4.0 and RR5/RR1≥7.0

B: 4.0>RR3/RR1>3.5 or 7.0>RR5/RR1>6.5

C: 3.5>RR3/RR1>3.0 or 6.5>RR5/RR1>5.2

D: RR3/RR1≤3.0 and RR5/RR1≤5.2

### <Evaluation Results>

In the polishing of the blanket wafer performed using the polishing liquid composition of each Example, RR (RR1, RR3, RR5) at each polishing pressure, an RRb/RRa value which is an evaluation index of RR, and values of RR3/RR1 and RR5/RR1 which are evaluation indexes of dishing reduction performance are shown in Tables 6 to 11.

A polishing liquid composition having a property of reduced RR at a low polishing pressure and exhibiting high RR at a high polishing pressure can obtain a good polished surface with reduced dishing of a pattern wafer without lowering RR.

In each of the polishing liquid compositions of Examples, RR was reduced at the time of low polishing pressure, and high RR was exhibited at the time of high polishing pressure, and RR3/RR1 and RR5/RR1 were large. In addition, since the decrease in RR3 was small, RRb/RRa was also large. On the other hand, in the case of Comparative Examples 1 and 2 in which no additive was added, the RR was substantially proportional to the polishing pressure. In Comparative Examples 4, 5, and 9, RR was significantly reduced at the all polishing pressures, and neither RR nor dishing reduction performance satisfied the acceptance criteria. In Comparative Examples 3 and 6 to 8, although a relatively high RR was exhibited at each polishing pressure, the RR at a low polishing pressure was not significantly suppressed, and thus the dishing reduction performance was insufficient.

TABLE 6

| | | | Example 1 | Example 2 | Example 3 | Example 4 | Example 5 | Example 6 | Example 7 | Example 8 | Example 9 |
|---|---|---|---|---|---|---|---|---|---|---|---|
| Polishing | Additives | | Polymer A | Polymer B | Polymer C | Polymer D | Polymer E | Polymer F | Polymer G | Polymer H | Polymer I |
| liquid | Polymer | 1st | AME-400 | AME-400 | AME-400 | AME-400 | AME-400 | AME-400 | AME-400 | AME-400 | AME-400 |
| composition | structure | monomer | | | | | | | | | |
| | | 2nd | EA | EA | EA | EA | EA | NIPAM | NIPAM | NIPAM | NIPAM |
| | | monomer | | | | | | | | | |
| | | 2nd | 18.19 | 18.19 | 18.19 | 18.19 | 18.19 | 21.63 | 21.63 | 21.63 | 21.63 |
| | | monomer | | | | | | | | | |
| | | SP value | | | | | | | | | |
| | | (J/cm³)^{0.5} | | | | | | | | | |
| | | 1st block | 94.9 | 95.1 | 94.9 | 94.9 | 94.9 | 95.3 | 95.1 | 95.1 | 95.1 |
| | | ratio (wt %) | | | | | | | | | |
| | | 2nd block | 5.1 | 4.9 | 5.1 | 5.1 | 5.1 | 4.7 | 4.9 | 4.9 | 4.9 |
| | | ratio (wt %) | | | | | | | | | |
| | Abrasive grain | | Ceria | Ceria | Ceria | Ceria | Ceria | Ceria | Ceria | Ceria | Ceria |
| Evaluation | Measured | RR1 | 45 | 36 | 55 | 66 | 58 | 45 | 40 | 72 | 70 |
| | RR | RR3 | 232 | 180 | 220 | 230 | 159 | 226 | 180 | 240 | 180 |
| | (mm/min) | RR5 | 386 | 330 | 361 | 380 | 325 | 390 | 280 | 400 | 400 |
| | Evaluation | RRb/RRa | 0.94 | 0.73 | 0.89 | 0.93 | 0.65 | 0.92 | 0.73 | 0.98 | 0.73 |
| | index | RR3/RR1 | 5.2 | 5.0 | 4.0 | 3.5 | 2.7 | 5.0 | 4.5 | 3.3 | 2.6 |
| | | RR5/RR1 | 8.6 | 9.2 | 6.6 | 5.8 | 5.6 | 8.7 | 7.0 | 5.6 | 5.7 |
| | Performance | RR | A | B | A | A | C | A | B | A | B |
| | | Dishing | A | A | B | C | C | A | A | C | C |
| | | reduction | | | | | | | | | |

TABLE 7

| | | | Example | Example | Example | Example | Example | Example | Example | Example | Example |
|---|---|---|---|---|---|---|---|---|---|---|---|
| | | | 10 | 11 | 12 | 13 | 14 | 15 | 16 | 17 | 18 |
| Polishing | Additives | | Polymer | Polymer | Polymer | Polymer | Polymer | Polymer | Polymer | Polymer | Polymer |
| liquid | | | J | K | L | M | N | O | P | Q | R |
| composition | Polymer | 1st monomer | AME-400 | AME-400 | AME-400 | AME-400 | AME-400 | AME-400 | AME-400 | AME-400 | AME-400 |
| | structure | 2nd monomer | BA | MA | HexA | TBAM | DMAA | DEAA | HEAA | DPM-A | HEA |
| | | 2nd monomer | 18.04 | 18.31 | 17.94 | 20.85 | 21.67 | 20.74 | 29.54 | 17.99 | 25.47 |
| | | SP value | | | | | | | | | |
| | | (J/cm³)^{0.5} | | | | | | | | | |
| | | 1st block | 94.9 | 95.0 | 95.1 | 95.6 | 95.3 | 95.2 | 95.2 | 95.1 | 94.9 |
| | | ratio (wt %) | | | | | | | | | |
| | | 2nd block | 5.1 | 5.0 | 4.9 | 4.4 | 4.7 | 4.8 | 4.8 | 4.9 | 5.1 |
| | | ratio (wt %) | | | | | | | | | |
| | Abrasive grain | | Ceria | Ceria | Ceria | Ceria | Ceria | Ceria | Ceria | Ceria | Ceria |
| Evaluation | Measured | RR1 | 43 | 60 | 66 | 48 | 66 | 60 | 45 | 58 | 56 |
| | RR | RR3 | 187 | 231 | 152 | 230 | 190 | 180 | 145 | 223 | 165 |
| | (nm/min) | RR5 | 340 | 390 | 380 | 400 | 400 | 380 | 268 | 410 | 318 |
| | Evaluation | RRb/RRa | 0.76 | 0.94 | 0.62 | 0.93 | 0.77 | 0.73 | 0.59 | 0.91 | 0.67 |
| | index | RR3/RR1 | 4.3 | 3.9 | 2.3 | 4.8 | 2.9 | 3.0 | 3.2 | 3.8 | 2.9 |
| | | RR5/RR1 | 7.9 | 6.5 | 5.8 | 8.3 | 6.1 | 6.3 | 6.0 | 7.1 | 5.7 |
| | Performance | RR | B | A | C | A | B | B | C | A | C |
| | | Dishing | A | B | C | A | C | C | 0 | B | C |
| | | reduction | | | | | | | | | |

TABLE 8

| | | | Example | Example | Example | Example | Example | Example | Example | Example |
|---|---|---|---|---|---|---|---|---|---|---|
| | | | 19 | 20 | 21 | 22 | 23 | 24 | 25 | 26 |
| Polishing | Additives | | Polymer | Polymer | Polymer | Polymer | Polymer | Polymer | Polymer | Polymer |
| liquid | | | S | T | U | V | W | X | Y | Z |
| composition | Polymer | 1st monomer | AME-400 | AME-400 | AME-400 | AME-400 | AME-400 | AME-400/ | AME-400/ | AME-400/ |
| | structure | | | | | | | TEA | NIPAM | PME-400 |
| | | 2nd monomer | EA | EA | NIPAM | NIPAM | — | — | — | EA |
| | | 2nd monomer | 18.19 | 18.19 | 21.63 | 21.63 | — | — | — | 18.19 |
| | | SP value (J/cm³)^{0.5} | | | | | | | | |
| | | 1st block ratio (wt %) | 90.0 | 82.1 | 90.8 | 83.2 | 100 | 100 | 100 | 93.7 |
| | | 2nd block ratio (wt %) | 10.0 | 17.9 | 9.2 | 16.8 | — | — | — | 6.3 |
| | Abrasive grain | | Ceria | Ceria | Ceria | Ceria | Ceria | Ceria | Ceria | Ceria |
| Evaluation | Measured | RR1 | 45 | 40 | 45 | 48 | 80 | 65 | 65 | 55 |
| | RR | RR3 | 180 | 136 | 162 | 150 | 210 | 210 | 212 | 210 |
| | (nm/min) | RR5 | 300 | 230 | 280 | 298 | 440 | 402 | 410 | 380 |
| | Evaluation | RRb/RRa | 0.73 | 0.55 | 0.66 | 0.61 | 0.85 | 0.85 | 0.86 | 0.85 |
| | index | RR3/RR1 | 4.0 | 3.4 | 3.6 | 3.1 | 2.6 | 3.2 | 3.3 | 3.8 |
| | | RR5/RR1 | 6.7 | 5.8 | 6.2 | 6.2 | 5.5 | 6.2 | 6.3 | 6.9 |
| | Performance | RR | B | C | C | C | A | A | A | A |
| | | Dishing reduction | B | C | B | C | C | C | C | B |

TABLE 9

| | | | Example | Example | Example | Example | Example | Example | Example |
|---|---|---|---|---|---|---|---|---|---|
| | | | 27 | 28 | 29 | 30 | 31 | 32 | 33 |
| Polishing | Additives | | Polymer | Polymer | Polymer | Polymer | Polymer | Polymer | Polymer |
| liquid | | | a | b | c | d | e | f | g |
| composition | Polymer | 1st monomer | AME-400/ | MTG-A | MTG-A | AM- | AM- | AE-400 | AE-400 |
| | structure | | PME-400 | | | 230G | 230G | | |
| | | 2nd monomer | NIPAM | EA | NIPAM | EA | NIPAM | EA | NIPAM |
| | | 2nd monomer | 21.63 | 18.19 | 21.63 | 18.19 | 21.63 | 18.19 | 21.63 |
| | | SP value (J/cm³)^{0.5} | | | | | | | |
| | | 1st block ratio (wt %) | 94.2 | 94.6 | 95.3 | 94.9 | 95. | 94.6 | 95.2 |
| | | 2nd block ratio (wt %) | 5.8 | 5.4 | 4.7 | 5.1 | 4.9 | 5.4 | 4.8 |
| | Abrasive grain | | Ceria | Ceria | Ceria | Ceria | Ceria | Ceria | Ceria |
| Evaluation | Measured | RR1 | 60 | 55 | 58 | 56 | 60 | 62 | 50 |
| | RR | RR3 | 220 | 150 | 162 | 156 | 160 | 185 | 150 |
| | (nm/min) | RR5 | 410 | 333 | 340 | 330 | 320 | 350 | 325 |
| | Evaluation | RRb/RRa | 0.89 | 0.61 | 0.66 | 0.63 | 0.65 | 0.75 | 0.61 |
| | index | RR3/RR1 | 3.7 | 2.7 | 2.8 | 2.8 | 2.7 | 3.0 | 3.0 |
| | | RR5/RR1 | 6.8 | 6.1 | 5.9 | 5.9 | 5.3 | 5.6 | 6.5 |
| | Performance | RR | A | C | C | C | C | B | C |
| | | Dishing reduction | B | C | C | C | C | C | C |

TABLE 10

| | | | Example | Example | Example | Example | Example | Example |
|---|---|---|---|---|---|---|---|---|
| | | | 34 | 35 | 36 | 37 | 38 | 39 |
| Polishing | Additives | | Polymer | Polymer | Polymer | Polymer | Polymer | Polymer |
| liquid | | | h | i | j | k | A | F |
| composition | Polymer | 1st monomer | AME-400/ | AME-400/ | AME-400 | AME-400 | AME-400 | AME-400 |
| | structure | | ACMO | ACMO | | | | |
| | | 2nd monomer | EA | NIPAM | EA | NIPAM | EA | NIPAM |
| | | 2nd monomer | 18.19 | 21.63 | 18.19 | 21.63 | 18.19 | 21.63 |
| | | SP value (J/cm³)^{0.5} | | | | | | |
| | | 3rd monomer | — | — | TBAM | TBAM | — | — |
| | | 3rd monomer | — | — | 20.85 | 20.85 | — | — |
| | | SP value (J/cm³)^{0.5} | | | | | | |
| | | 1st block ratio (wt %) | 94.6 | 94.3 | 95.2 | 95.3 | 100 | 94.9 |
| | | 2nd block ratio (wt %) | 5.4 | 5.7 | 2.5 | 2.3 | — | 5.1 |
| | | 3rd block ratio (wt %) | — | — | 2.3 | 2.4 | — | — |
| | Abrasive grain | | Ceria | Ceria | Ceria | Ceria | Silica | Silica |
| Evaluation | Measured | RR1 | 50 | 51 | 57 | 52 | 30 | 37 |
| | RR | RR3 | 220 | 223 | 230 | 221 | 100 | 112 |
| | (nm/min) | RR5 | 379 | 360 | 425 | 425 | 202 | 210 |
| | Evaluation | RRb/RRa | 0.89 | 0.91 | 0.93 | 0.90 | 0.66 | 0.74 |
| | index | RR3/RR1 | 4.4 | 4.4 | 4.0 | 4.3 | 3.3 | 3.0 |
| | | RR5/RR1 | 7.6 | 7.1 | 7.5 | 8.2 | 6.7 | 5.7 |
| | Performance | RR | A | A | A | A | C | B |
| | | Dishing reduction | A | A | A | A | B | C |

TABLE 11

| | | | Com- | Com- | Com- | Com- | Com- | Com- | Com- | Com- | Com- |
|---|---|---|---|---|---|---|---|---|---|---|---|
| | | | parative | parative | parative | parative | parative | parative | parative | parative | parative |
| | | | Ex- | Ex- | Ex- | Ex- | Ex- | Ex- | Ex- | Ex- | Ex- |
| | | | ample 1 | ample 2 | ample 3 | ample 4 | ample 5 | ample 6 | ample 7 | ample 8 | ample 9 |
| Polishing | Additives | | None | None | XL-80 | Polymer l | Polymer m | Polymer n | Polymer o | Polymer p | Polymer q |
| liquid | Polymer | 1st monomer | — | — | — | AA | AME-400 | AME-400 | AME-400/ | AME-400/ | AA |
| composition | structure | | | | | | | | EA | NIPAM | |
| | | 2nd monomer | — | — | — | — | AA | — | — | — | NIPAM |
| | | 2nd monomer | — | — | — | — | 22.68 | — | — | — | 21.63 |
| | | SP value | | | | | | | | | |
| | | (J/cm³)^{0.5} | | | | | | | | | |
| | | 1st block | — | — | — | 100 | 94.9 | 100 | 100 | 100 | 95.4 |
| | | ratio (wt %) | | | | | | | | | |
| | | 2nd block | — | — | — | — | 5.1 | — | — | — | 4.6 |
| | | ratio (wt %) | | | | | | | | | |
| | Abrasive grain | | Ceria | Silica | Ceria | Ceria | Ceria | Ceria | Ceria | Ceria | Ceria |
| Evaluation | Measured | RR1 | 110 | 60 | 85 | 45 | 50 | 75 | 70 | 68 | 45 |
| | RR | RR3 | 246 | 151 | 220 | 95 | 120 | 220 | 200 | 170 | 95 |
| | (nm/min) | RR5 | 500 | 262 | 380 | 110 | 200 | 330 | 344 | 350 | 220 |
| | Evaluation | RRb/RRa | 1.00 | 1.00 | 0.89 | 0.39 | 0.49 | 0.89 | 0.81 | 0.69 | 0.39 |
| | index | RR3/RR1 | 2.2 | 2.5 | 2.6 | 2.1 | 2.4 | 2.9 | 2.9 | 2.5 | 2.1 |
| | | RR5/RR1 | 4.5 | 4.4 | 4.5 | 2.4 | 4.0 | 4.4 | 4.9 | 5.1 | 4.9 |
| | Performance | RR | A | A | A | D | D | A | B | C | D |
| | | Dishing | D | D | D | D | D | D | D | D | D |
| | | reduction | | | | | | | | | |

1. An additive for chemical mechanical polishing comprising a polymer (P),
wherein the polymer (P) contains a structural unit (A) derived from a vinyl monomer having a -(LO)n-R group,
a total content of a structural unit derived from a monomer(s) containing one or more functional groups selected from the group consisting of a carboxylic acid group, a phosphoric acid group, a phosphonic acid group, a sulfuric acid group, a sulfonic acid group, and salts thereof is 0 to 0.6 mass % in the polymer (P), and
a dispersity (PDI) of the polymer (P), which is represented by weight average molecular weight (Mw)/number average molecular weight (Mn), is 2.0 or less,
wherein L represents an alkylene group having 4 or less carbon atoms, n represents an arbitrary integer of 3 to 150, and R represents a hydrogen atom or a monovalent hydrocarbon group having 1 to 4 carbon atoms.

2. The additive according to claim 1, wherein a number average molecular weight (Mn) of the polymer (P) is 1,000 to 100,000.

3. The additive according to claim 1, wherein the polymer (P) further contains a structural unit (B) derived from at least one monomer except for the vinyl monomer having the -(LO)n-R group, the monomer being selected from the group consisting of an amide group-containing vinyl monomer and an ester group-containing vinyl monomer.

4. The additive according to claim 3, wherein the structural unit (B) is derived from a (meth)acrylic acid ester and/or a (meth)acrylic acid amide type monomer.

5. The additive according to claim 3, wherein the structural unit (B) is derived from a monomer having an SP value of 17 to 25 (J/cm³)^{0.5} as calculated by a Fedors' estimation method.

6. The additive according to claim 1, wherein the polymer (P) is a block polymer.

7. The additive according to claim 1, wherein
the polymer (P) contains a polymer block A and a polymer block B,
the polymer block A has the structural unit (A), and
the polymer block B has the structural unit (B).

8. The additive according to claim 7, wherein
a ratio (A/B) of the polymer block A to the polymer block B in the polymer (P) is 50/50 to 99.9/0.1 in mass ratio.

9. A polishing liquid composition for chemical mechanical polishing used for surface planarization of at least one of an insulating layer and a wiring layer, the polishing liquid composition comprising the additive according to claim 1 and cerium oxide and/or silica.

10. A method for producing an additive for a chemical mechanical polishing liquid, the additive containing a polymer, comprising;
producing the polymer by a living radical polymerization method,
wherein the polymer contains a structural unit derived from a vinyl monomer having a -(LO)n-R group,
a total content of a structural unit derived from a monomer containing one or more functional groups selected from the group consisting of a carboxylic acid group, a phosphoric acid group, a phosphonic acid group, a sulfuric acid group, a sulfonic acid group, and salts thereof is 0 to 0.6 mass % in the polymer, and
a dispersity (PDI) of the polymer, which is represented by weight average molecular weight (Mw)/number average molecular weight (Mn), is 2.0 or less,
wherein L represents an alkylene group having 4 or less carbon atoms, n represents an arbitrary integer of 3 to 150, and R represents a hydrogen atom or a monovalent hydrocarbon group having 1 to 4 carbon atoms.
